(19) United States
(12) Patent Application Publication
(10) Pub. No.: US 2014/0035688 A1
(43) Pub. Date: Feb. 6, 2014

(54) OSCILLATOR

(71) Applicant: SAMSUNG ELECTRO-MECHANICS CO., LTD., Gyunggi-do (KR)

(72) Inventor: Joo Yul KO, Gyunggi-do (KR)

(73) Assignee: SAMSUNG ELECTRO-MECHANICS CO., LTD., Gyunggi-do (KR)

(21) Appl. No.: 13/660,491

(22) Filed: Oct. 25, 2012

(30) Foreign Application Priority Data
Jul. 31, 2012 (KR) 10-2012-0084159

(51) Int. Cl. H03K 3/26

(52) U.S. Cl. 331/111

(57) ABSTRACT

There is provided an oscillator providing a clock signal having a uniform duty ratio by generating a toggled voltage by charging and discharging a capacitor with a voltage irrespective of a temperature from a band gap circuit. The oscillator includes: a band gap circuit providing a band gap reference voltage having a pre-set voltage level; a voltage-current conversion unit converting the band gap reference voltage from the band gap circuit into a current; a charging/discharging unit charging/discharging the converted current and providing a triangle wave signal; and a T flip-flop logically operating a pulse signal according to a maximum value of the triangle wave signal from the charging/discharging unit and providing a clock signal having a fixed duty.

### CROSS-REFERENCE TO RELATED APPLICATIONS

This application claims the priority of Korean Patent Application No. 10-2012-0084159 filed on Jul. 31, 2012, in the Korean Intellectual Property Office, the disclosure of which is incorporated herein by reference.

### BACKGROUND OF THE INVENTION

1. Field of the Invention

The present invention relates to an oscillator providing a clock signal having a certain interval.

2. Description of the Related Art

In general, an oscillator, which generates an oscillation signal by itself through oscillation, without using an external oscillation element, has been extensively used to provide a timing signal in electronic devices including computers, systems, communications devices, and the like.

In detail, in a semiconductor memory device, an IC chip, a micro-controller, and a charge pump circuit, a clock signal is used to operate internal elements thereof, and an oscillator is a device for generating such a clock signal in an internal circuit. An oscillator may also be employed in a motor driving circuit in order to generate a reference clock signal required for driving a motor.

A clock signal as an output signal from a generally used oscillator has an interval greatly changed according to a level of an external voltage or a change in temperature. When the interval of a clock signal is changed according to a change factor, an operation of a system which operates in synchronization with a clock signal may be greatly affected.

In order to solve the defect, as disclosed in the related art document below, a constant current source connected to an inverter, or a circuit including a resistor, a capacitor, or a comparator to obtain an RC delay effect is commonly used. Even in this case, however, the interval of a clock signal may remain changed due to a level of an external voltage, a change in temperature, or the like.

### RELATED ART DOCUMENT

Korean Patent Laid Open Publication No. 10-2008-0045529

### SUMMARY OF THE INVENTION

An aspect of the present invention provides an oscillator providing a clock signal having a uniform duty ratio by generating a toggled voltage by charging and discharging a capacitor with a voltage, irrespective of a temperature from a band gap circuit.

According to an aspect of the present invention, there is provided an oscillator including: a band gap circuit providing a band gap reference voltage having a pre-set voltage level; a voltage-current conversion unit converting the band gap reference voltage from the band gap circuit into a current; a charging/discharging unit charging/discharging the converted current from the voltage-current conversion unit and providing a triangle wave signal; and a T flipflop logically operating a pulse signal according to a maximum value of the triangle wave signal from the charging/discharging unit and providing a clock signal having a fixed duty.

The oscillator may further include a current mirror mirroring the converted current from the voltage-current conversion unit.

The voltage-current conversion unit may include: a first comparator comparing the band gap reference voltage and a detected voltage; a switch swinging the current mirroring operation of the current mirror according to a comparison result from the first comparator; and a resistor detecting a current flowing in the switch and providing the detected voltage to the first comparator.

The charging/discharging unit may include: a capacitor charging/discharging the mirrored current from the current mirror; a charging/discharging switch controlling charging/discharging of the current to and from the capacitor; and a second comparator comparing a voltage of the capacitor with a pre-set reference voltage and controlling switching of the charging/discharging switch.

The T flipflop may include: a clock terminal receiving the triangle wave signal from the charging/discharging unit; a data terminal receiving an inverted output signal; an output terminal maintaining or changing a signal input to the data terminal according to a triangle wave signal from the clock terminal and providing the clock signal; and an inverting output terminal inverting a signal from the output terminal and transferring the inverted signal to the data terminal.

The oscillator may further include: a buffer buffering a clock signal from the T flip-flop.

According to another aspect of the present invention, there is provided an oscillator including: a band gap circuit providing a band gap reference voltage having a pre-set voltage level; a voltage-current conversion unit converting the band gap reference voltage from the band gap circuit into a current; a current mirror mirroring the converted current from the voltage-current conversion unit; a charging/discharging unit charging/discharging the mirrored current from the current mirror and providing a triangle wave signal; and a T flip-flop logically operating a pulse signal according to a maximum value of the triangle wave signal from the charging/discharging unit and providing a clock signal having a fixed duty.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating a configuration of an oscillator according to an embodiment of the present invention;

FIG. 2 is a view illustrating a T flipflop employed in the oscillator according to an embodiment of the present invention; and

FIG. 3 is a graph illustrating signal waveforms of major parts of the oscillator illustrated in FIG. 1 according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

A case in which any one part is connected to another part includes a case in which the parts are directly connected to each other and a case in which the parts are indirectly connected to each other with other elements interposed therebetween.

In addition, unless explicitly described otherwise, “comprising” any components will be understood to imply the inclusion of other components but not the exclusion of any other components.

Embodiments of the present invention will now be described in detail with reference to the accompanying drawings.

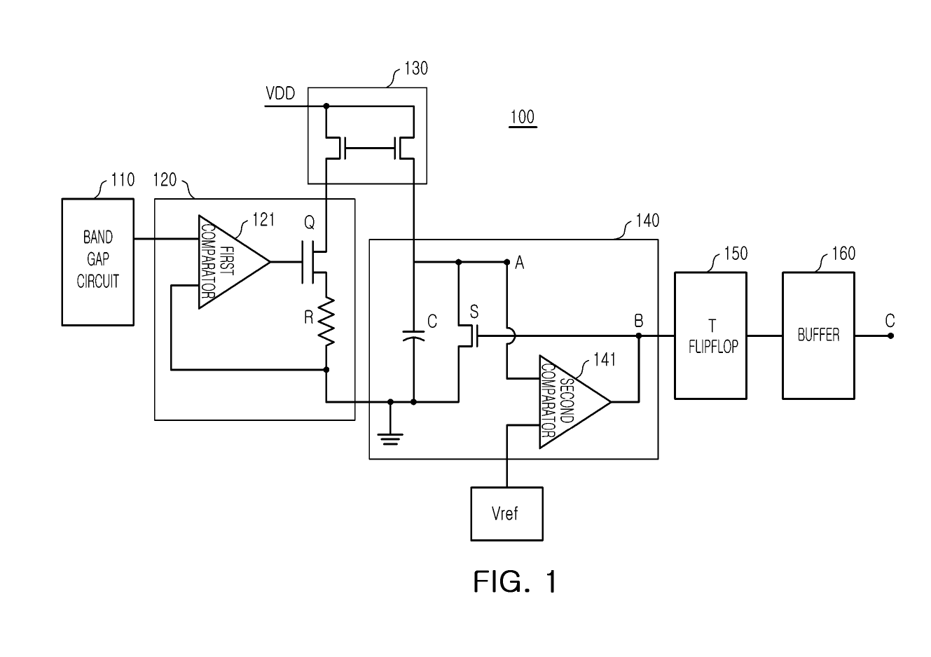

FIG. 1 is a schematic view illustrating a configuration of an oscillator according to an embodiment of the present invention.

Referring to FIG. 1, an oscillator 100 according to an embodiment of the present invention may include a band gap circuit 110, a voltage-current conversion unit 120, a current mirror 130, a charging/discharging unit 140, a T flipflop 150, and a buffer 160.

The band gap circuit 110 may provide a band gap reference voltage irrespective of a change in temperature.

In detail, the band gap circuit 110, a circuit for supplying a reference voltage or a reference current having a certain voltage level not affected by a change in a power source voltage, a change in temperature, and a process variation according to output characteristics that a negative (−) temperature coefficient and a positive (+) temperature coefficient are canceled out, may generate a band gap voltage having a uniform voltage level according to a supplied power.

The voltage-current conversion unit 120 may convert an input voltage level into a corresponding current level.

To this end, the voltage-current conversion unit 120 may include a first comparator 121, a switch Q, and a resistor R.

The first comparator 121 may receive a band gap voltage input to a first input terminal (−) and a detection voltage fed back and input to the second input terminal (+), and compare the received band gap voltage and the detection voltage to generate a comparison result having a uniform voltage level.

The switch Q is connected between a first node to which a power source voltage VDD is supplied and the resistor R. The switch Q may be switched in response to the comparison result output from the first comparator 121 to form a current path between the first node and the resistor R.

The switch Q according to an embodiment of the present invention may be implemented as a PMOS transistor or an NMOS transistor. For example, when the switch Q is implemented as a PMOS transistor, the switch Q may perform a switching operation in response to the comparison result having a first logic level (e.g., a low level), and when the switch Q is implemented as an NMOS transistor, the switch Q may perform a switching operation in response to the comparison result having a second logic level (e.g., a high level).

The resistor R may be connected between the switch Q and a ground, and provide the detection voltage.

A current may be generated according to switching of the switch Q, and in this case, it may be generated according to a formation of a current path along which the power source voltage VDD flows.

The current mirror 130 may mirror the current generated according to switching of the switch Q in the voltage-current conversion unit 120 and transfer the same to the charging/discharging unit 140.

To this end, the current mirror 130 may include two transistors whose gates are commonly connected.

The two transistors receive the power source voltage VDD and may have a structure in which the gates thereof are commonly connected, so a current flowing in one transistor may be mirrored in the other transistor.

The charging/discharging unit 140 may charge/discharge the mirrored current to provide a triangle wave signal.

To this end, the charging/discharging unit 140 may include a capacitor C, a charging/discharging switch S, and a second comparator 141.

The capacitor C may charge or discharge the mirrored current transferred from the other transistor of the current mirror 130.

The charging/discharging switch S may be switched according to the comparison result of the second comparator 141 to charge or discharge a current to or from the capacitor C.

The second comparator 141 may compare a voltage charged in the capacitor C with a pre-set reference voltage and provide the comparison result to the charging/discharge switch S to control switching of the charging/discharging switch S.

The charging/discharging switch S according to an embodiment of the present invention may be implemented as a PMOS transistor or an NMOS transistor. For example, when the charging/discharging switch S is implemented as a PMOS transistor, the charging/discharging switch S may perform a switching operation in response to a comparison result from the second comparator 141 having a first logic level (e.g., a low level), and when the charging/discharging switch S is implemented as a NMOS transistor, the charging/discharging switch S may perform a switching operation in response to a comparison result from the second comparator 141 having a second logic level (e.g., a high level).

The T flipflop 150 may logically operate a triangle wave signal from the charging/discharging unit 140 and provide a clock signal having a fixed duty.

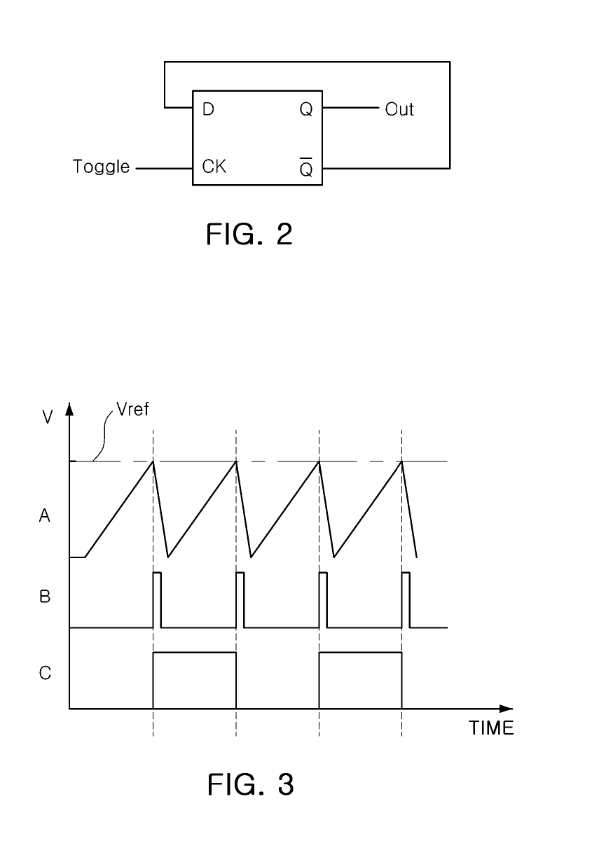

FIG. 2 is a view illustrating the T flipflop employed in the oscillator according to an embodiment of the present invention.

Referring to FIGS. 1 and 2, the T flipflop 150 may include a clock terminal CK receiving a pulse signal from the charging/discharging unit 140, a data terminal D receiving an inverted output signal, an output terminal Q maintaining or changing an output of a signal input to the data terminal D according to a pulse signal from the clock terminal CK and providing a clock signal, and an inverting output terminal Q inverting a signal from the output terminal Q and transferring the same to the data terminal D.

The T flipflop 150, having a structure using a D flip-flop, may change a level of an output signal when a signal input to the clock terminal CK has a high level.

This may be expressed by equation 1 shown below.

Qₙₑₓₜ=T⊕Q=T Q̅+ T̅Q (Equation 1)

According to the foregoing equation, logic results of the T flipflop 150 may be expressed as shown in Table below.

TABLE

| T | Q | Q̅ | Characteristics |
|---|---|---|---|
| 0 | 0 | 0 | Output maintained |
| 0 | 1 | 1 | Output maintained |
| 1 | 0 | 1 | Output changed |
| 1 | 1 | 0 | Output changed |

FIG. 3 is a graph illustrating signal waveforms of major parts of the oscillator illustrated in FIG. 1 according to an embodiment of the present invention.

Referring to FIGS. 1, 2, and 3, signal waveforms of node A, node B, and node C are major parts of the oscillator of the present invention.

A signal A of node A indicates a triangle wave signal according to a current charged to or discharged from the capacitor C, a signal B of node B indicates a pulse signal generated according to an operation of the charging/discharging switch Q when a voltage level of the triangle wave signal and that of the reference voltage are the same as a result of a comparison therebetween by the second comparator 141. The signal C of node C may be a clock signal having a fixed duty whose level was inverted when the pulse signal had a high level after being input to the clock terminal of the T flip-flop.

In addition, the oscillator 100 may further include the buffer 160. The buffer 160 may buffer the clock signal from the T flipflop 150 and finally output the same.

As set forth above, according to embodiments of the invention, a clock signal having a uniform duty ratio may be provided by generating a toggled voltage by charging and discharging the capacitor with a voltage irrespective of a temperature from the band gap circuit.

While the present invention has been shown and described in connection with the embodiments thereof, it will be apparent to those skilled in the art that modifications and variations can be made without departing from the spirit and scope of the invention as defined by the appended claims.

What is claimed is:

1. An oscillator comprising:
a band gap circuit providing a band gap reference voltage having a pre-set voltage level;
a voltage-current conversion unit converting the band gap reference voltage from the band gap circuit into a current;
a charging/discharging unit charging/discharging the converted current from the voltage-current conversion unit and providing a triangle wave signal; and
a T flipflop logically operating a pulse signal according to a maximum value of the triangle wave signal from the charging/discharging unit and providing a clock signal having a fixed duty.

2. The oscillator of claim 1, further comprising a current mirror mirroring the converted current from the voltage-current conversion unit.

3. The oscillator of claim 2, wherein the voltage-current conversion unit includes:
a first comparator comparing the band gap reference voltage and a detected voltage;
a switch swinging the current mirroring operation of the current mirror according to a comparison result from the first comparator; and
a resistor detecting a current flowing in the switch and providing the detected voltage to the first comparator.

4. The oscillator of claim 2, wherein the charging/discharging unit includes:
a capacitor charging/discharging the mirrored current from the current mirror;
a charging/discharging switch controlling charging/discharging of the current to and from the capacitor; and
a second comparator comparing a voltage of the capacitor with a pre-set reference voltage and controlling switching of the charging/discharging switch.

5. The oscillator of claim 1, wherein the T flip-flop includes:
a clock terminal receiving the pulse signal from the charging/discharging unit;
a data terminal receiving an inverted output signal;
an output terminal maintaining or changing an output of a signal input to the data terminal according to a pulse signal from the clock terminal and providing the clock signal; and
an inverting output terminal inverting a signal from the output terminal and transferring the inverted signal to the data terminal.

6. The oscillator of claim 1, further comprising a buffer buffering a clock signal from the T flip-flop.

7. An oscillator comprising:
a band gap circuit providing a band gap reference voltage having a pre-set voltage level;
a voltage-current conversion unit converting the band gap reference voltage from the band gap circuit into a current;
a current mirror mirroring the converted current from the voltage-current conversion unit;
a charging/discharging unit charging/discharging the mirrored current from the current mirror and providing a triangle wave signal; and
a T flipflop logically operating a pulse signal according to a maximum value of the triangle wave signal from the charging/discharging unit and providing a clock signal having a fixed duty.

8. The oscillator of claim 7, wherein the voltage-current conversion unit includes:
a first comparator comparing the band gap reference voltage and a detected voltage;
a switch swinging the current mirroring operation of the current mirror according to a comparison result from the first comparator; and
a resistor detecting a current flowing in the switch and providing the detected voltage to the first comparator.

9. The oscillator of claim 7, wherein the charging/discharging unit includes:
a capacitor charging/discharging the mirrored current from the current mirror;
a charging/discharging switch controlling charging/discharging of the current to and from the capacitor; and
a second comparator comparing a voltage of the capacitor with a pre-set reference voltage and controlling switching of the charging/discharging switch.

10. The oscillator of claim 7, wherein the T flip-flop includes:
a clock terminal receiving the pulse signal from the charging/discharging unit;
a data terminal receiving an inverted output signal;
an output terminal maintaining or changing an output of a signal input to the data terminal according to the pulse signal from the clock terminal and providing the clock signal; and
an inverting output terminal inverting a signal from the output terminal and transferring the inverted signal to the data terminal.

11. The oscillator of claim 7, further comprising a buffer buffering the clock signal from the T flip-flop.
